(19) United States
(12) Patent Application Publication
(10) Pub. No.: US 2007/0018168 A1
(43) Pub. Date: Jan. 25, 2007

(54) Thin film transistor substrate, display device, and method of fabricating the same

(76) Inventors: Joon Hak Oh, Seoul (KR); Jong Hyun Seo, Seoul (KR)

Correspondence Address: CANTOR COLBURN, LLP, 55 GRIFFIN ROAD SOUTH, BLOOMFIELD, CT, 06002, US

(21) Appl. No.: 11/355,765

(22) Filed: Feb. 16, 2006

(30) Foreign Application Priority Data
Jul. 22, 2005 (KR) 10-2005-0066864

(51) Int. Cl. H01L 29/04

(52) U.S. Cl. 257/72

(57) ABSTRACT

A thin film transistor (“TFT”) substrate includes a gate line formed on a base substrate, a data line insulated from the gate line, and a TFT formed at the intersection between the gate line and the data line. A line width of the gate line is greater than a line width of the data line. The data line includes a first data line insulated from and intersected with the gate line and a second data line intersecting the first data line and having an end electrically connected to the data line. Further, a drain electrode of the TFT is spaced apart from the data line by a predetermined interval. A display device comprising the TFT substrate and a method of fabricating the TFT substrate are also disclosed. Thus, the present invention can be prepared against the misalignment due to the expansion or shrinkage of the substrate during the process of fabricating the LCD device using a flexible substrate.

This application claims priority to Korean Patent Application No. 10-2005-0066864, filed on Jul. 22, 2005 and all the benefits accruing therefrom under 35 U.S.C. § 119, and the contents of which in its entirety are herein incorporated by reference.

### BACKGROUND OF THE INVENTION

1. Field of the Invention

The present invention relates to a pad structure, a thin film transistor, a display device including the pad structure and the thin film transistor substrate, and a method of fabricating the same. More particularly, the present invention relates to a pad structure and a thin film transistor for preventing against misalignment due to expansion or shrinkage of a flexible substrate during a process of fabricating a display device using the flexible substrate, the display device including the pad structure and the thin film transistor, and the method of fabricating the same.

2. Description of the Related Art

In general, a liquid crystal display (“LCD”) device includes a liquid crystal panel for displaying information by means of the electrical and optical properties of liquid crystal, a driving circuit electrically connected with the liquid crystal panel to drive the liquid crystal panel, and a backlight assembly.

FIG. 1 is a schematic view illustrating the configuration of a general LCD device. A liquid crystal panel 10 includes a thin film transistor (“TFT”) substrate, a color filter substrate facing the TFT substrate, and a liquid crystal material injected between the two substrates. In the case of a general TFT substrate, a plurality of gate lines are formed to intersect a plurality of data lines. A TFT and a pixel electrode are formed as switching devices at the intersection between the corresponding gate and data lines, and input pads 20 electrically connected to the driving circuit are formed at first ends of the gate and data lines. In addition, the driving circuit includes a source driver integrated circuit (“IC”) that is electrically connected to the input pad formed at a first end of the data line to apply gray scale voltage to the data line, a gate driver IC that is electrically connected to the input pad formed at a first end of the gate line to apply a control signal of the TFT to each gate line, and a printed circuit board (“PCB”) 30 on which active and passive elements for generating a variety of driving signals are mounted.

FIG. 2A shows a pixel on a TFT substrate of an LCD device according to the prior art, and FIG. 2B is a sectional view taken along line 2-2′ of FIG. 2A.

Referring to FIGS. 2A and 2B, a TFT substrate 1 of an LCD device includes a plurality of gate lines 2 arranged at regular intervals in parallel on a transparent insulating substrate 11 such as glass. A lower storage electrode 12 is arranged midway between two adjacent gate lines 2 in parallel with the gate lines 2. A gate electrode 7a of the TFT 7, which is formed on each pixel 6, is connected to each gate line 2. A gate insulating film 13 is formed on the entire surface of the transparent insulating substrate 11 including the gate lines 2 and the gate electrode 7a of the TFT 7. An active layer 14a and an ohmic contact layer 14b are formed on top of the gate insulating film 13 over the gate electrode 7a. A source electrode 7b and a drain electrode. 7c are formed at the peripheries of the active layer 14a and the ohmic contact layer 14b. The data line 3 is formed on the gate insulating film 13 at regular intervals in order to perpendicularly intersect each gate line 2. Each data line 3 is connected to the source electrode 7b of the TFT 7. Furthermore, the drain electrode 7c extends to form an upper storage electrode 16 which is connected to a pixel electrode 8. An interlayer insulating film 17 is formed on the TFT 7, the upper storage electrode 16, the gate line 2, and the data line 3, and a contact hole 18 is formed on the interlayer insulating film 17 in order to reach the upper storage electrode 16. The pixel electrode 8 is formed on the interlayer insulating film 17 over the entire surface of each pixel 6 and electrically connected to the upper storage electrode 16 through the contact hole 18.

The aforementioned conventional substrate of the LCD device is generally manufactured from a glass substrate. However, since the glass substrate is heavy and fragile, it is not suitable for a device that is lightweight, and it is not suitable for a device that has deformation acceptability and requires durability against external impact.

Accordingly, a flexible display device for replacing the conventional glass substrate with a flexible substrate is being studied and developed. The flexible display device is a next-generation display device that replaces the glass substrate used in the conventional display device with a thin, flexible substrate such as a plastic substrate. Since it is light, thin, and unbreakable due to its flexibility, and its production costs can be reduced, the flexible display device is likely to be used in a small terminal such as a smart card, a cell phone, a personal digital assistant (“PDA”), or the like.

Unlike the conventional glass substrate, however, the flexible substrate such as the plastic substrate has a problem in that its size can be changed due to the expansion or shrinkage of the substrate, depending on the manufacturing conditions. For example, a rate of change of deformation with temperature of the glass substrate is about 3˜5 ppm/° C., but that of the plastic substrate is about 50˜100 ppm/° C. In addition, the size of the plastic substrate can be changed when absorbing moisture. In such a case, the rate of change is about 3000 ppm.

In connection with this, FIG. 3 shows a graph plotting the misalignment of the TFT substrate using the plastic substrate in the flexible display device, where the misalignment levels of respective components caused by the expansion or shrinkage of the plastic substrate during the fabricating process of a 5- or 7-inch plastic substrate is compared with respect to the gate. As an example, in the case of the gate to Active 2 in a 7-inch flexible LCD device, a misalignment of about 37 μm occurs. Thus, margins of about 37 μm are required at both sides for manufacturing the TFT. Moreover, considering the size of the TFT, a width of at least 90 μm is necessary. However, the pixel size of the TFT in a 7-inch video graphics array (“VGA”) flexible LCD device is about 74×222 μm. Therefore, when the same structure as the conventional substrate is designed, a problem occurs in that the design cannot be prepared enough for the misalignment.

As described above, since unlike the conventional glass substrate, the flexible substrate such as the plastic substrate can expand or shrink depending upon the manufacturing conditions, the TFT cannot be properly fabricated if the design does not consider a margin for overcoming the misalignment of the substrate caused by its size change.

### BRIEF SUMMARY OF THE INVENTION

The present invention solves the aforementioned problems in the art by providing a thin film transistor (“TFT”) substrate, a pad structure, a display device including the TFT substrate and the pad structure, and a method of fabricating the same for preparing against misalignment due to a size change of a flexible substrate, used in the TFT substrate, during a process of fabricating a liquid crystal display (“LCD”) device.

According to exemplary embodiments of the present invention, there is provided a TFT substrate including a gate line formed on a base substrate, a data line formed within the thin film transistor substrate and insulated from the gate line, and a TFT formed at an intersection between the gate line and the data line, wherein a line width of the gate line is at least greater than a line width of the data line, the data line including a first data line insulated from and intersected with the gate line and a second data line intersecting the first data line and having an end electrically connected to the first data line, and a drain electrode of the TFT spaced apart from the data line by a predetermined interval.

The line width of the gate line may be greater than a line width of the second data line, a width of the drain electrode, and the predetermined interval combined.

The TFT includes an active layer, and location of the active layer with respect to the gate and data lines may determine location of the gate electrode and source electrode, respectively.

The second data line may be formed in parallel to the gate line.

The drain electrode may be formed in parallel to the second data line.

The second data line may be formed completely over the gate line.

Preferably, the second data line is formed such that a first portion thereof is parallel to the gate line and a second portion thereof is parallel to the first data line.

The drain electrode may include a first section formed in parallel to the first data line and a second section parallel to the second data line.

The drain electrode may include a third section extending from the second section and formed in parallel to the first data line.

A storage electrode may be connected to the first and third sections of the drain electrode.

Preferably, a line width of the gate line is adjusted depending on an expansion and contraction rate of the base substrate.

The TFT substrate may further comprise a first storage electrode.

The first storage electrode may be formed from a protrusion of a gate line from an adjacent pixel of the TFT substrate.

Preferably, the first storage electrode is disposed in parallel to and spaced apart from the gate line by a predetermined interval.

The TFT substrate may further comprise a pixel electrode connected to the drain electrode via a contact hole.

The TFT substrate may comprise a second storage electrode electrically connected to the drain electrode and formed on the first storage electrode.

The TFT substrate may comprise a pixel electrode connected to the second storage electrode via a contact hole.

Preferably, the base substrate is a flexible substrate.

More preferably, the base substrate is made of a plastic material.

A pad may be formed on a first end of the data line, where a line width of the data line at the first end of the data line is greater than the line width of the data line adjacent the intersection, and the pad may have a width greater than the line width of the first end of the data line.

A contact hole may be provided at the pad, and the contact hole may have a width greater than the line width of the data line adjacent the intersection.

According to other exemplary embodiments of the invention, there is provided a display device having the aforementioned TFT substrate.

According to other further exemplary embodiments of the invention, there is provided a TFT substrate including a gate line formed on a base substrate, a data line formed within the TFT substrate and insulated from the gate line, and a TFT formed at the intersection of the gate line and the data line, wherein a line width of the gate line is at least greater than a line width of the data line, the data line including a pair of first data lines insulated from and intersected with the gate line and arranged in parallel to each other at a predetermined interval and a second data line electrically connected to the pair of first data lines, and a drain electrode of the TFT spaced apart from the data line by a predetermined interval.

According to still further exemplary embodiments of the invention, there is provided a method of fabricating a TFT substrate of a display device, the method including forming a gate line on a base substrate, forming a data line including a first data line insulated from and intersected with the gate line and a second data line intersecting the first data line and having an end electrically connected to the first data line, and arranging a drain electrode to be spaced apart from the second data line by a predetermined interval, wherein a line width of the gate line is at least greater than a line width of the second data line.

According to still further exemplary embodiments of the invention, there is provided a method of fabricating a TFT substrate of a display device, the method including forming a gate line on a base substrate, forming a pair of first data lines insulated from and intersected with the gate line and arranged in parallel to each other at a predetermined interval, and a second data line electrically connected to the pair of first data lines, and arranging a drain electrode to be spaced apart from the second data line by a predetermined interval, wherein a line width of the gate line is at least greater than a line width of the second data line.

According to still further exemplary embodiments of the invention, there is provided a method of fabricating a TFT substrate of a display device, the method including determining a maximum misalignment range between a gate line and elements of a TFT within the thin film transistor substrate and forming a line width of the gate line to be greater than the maximum misalignment range.

### BRIEF DESCRIPTION OF THE DRAWINGS

The above and other features and advantages of the present invention will become apparent from the following description of preferred embodiments given in conjunction with the accompanying drawings, in which:

FIG. 1 is a schematic view illustrating the configuration of a prior art liquid crystal display (“LCD”) device;

FIGS. 2A and 2B are views showing a pixel on a thin film transistor (“TFT”) substrate of an LCD device according to a prior art;

FIG. 3 is a graph plotting misalignment of the TFT substrate using a plastic substrate in a flexible display device;

FIG. 4 is a plan view of a first exemplary embodiment of a TFT substrate of an LCD device according to the present invention;

FIG. 5 is a plan view illustrating a state where the maximum alignment occurs in the first exemplary embodiment of the TFT substrate according to the present invention;

FIGS. 6A to 10B are plan views and sectional views showing an exemplary fabricating process of the first exemplary embodiment of the TFT substrate according to the present invention;

FIG. 11 is a plan view of a second exemplary embodiment of a TFT substrate of an LCD device according to the present invention;

FIG. 12 is a plan view of a third exemplary embodiment of a TFT substrate of an LCD device according to the present invention;

FIG. 13 is a plan view of a fourth exemplary embodiment of a TFT substrate of an LCD device according to the present invention;

FIG. 14 is a plan view of a fifth exemplary embodiment of a TFT substrate of an LCD device according to the present invention;

FIG. 15 is a plan view of a sixth exemplary embodiment of a TFT substrate of an LCD device according to the present invention;

FIG. 16A is a partial plan view showing a pad structure of the prior art LCD device; FIG. 16B shows a pad structure of the prior art LCD device having no misalignments, and FIGS. 16C and 16D show a pad structure of the prior art LCD device having a misalignment;

FIG. 17 is a plan view of an exemplary embodiment of a pad structure of the LCD device according to the present invention;

FIGS. 18A and 18B are enlarged views of an exemplary embodiment of the pad structure of the LCD device according to the present invention;

FIG. 18C is a sectional view of the exemplary pad structure of the LCD device according to the present invention taken along line 18-18′ in FIG. 18b;

FIG. 19A shows an exemplary embodiment of a tape carrier package (“TCP”) structure corresponding to the exemplary pad structure of the LCD device according to the present invention; and

FIG. 19B is a sectional view of the TCP taken along line 19-19′ shown in FIG. 19a.

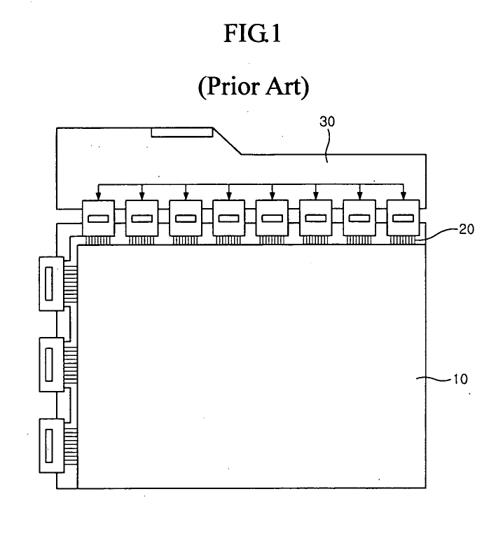

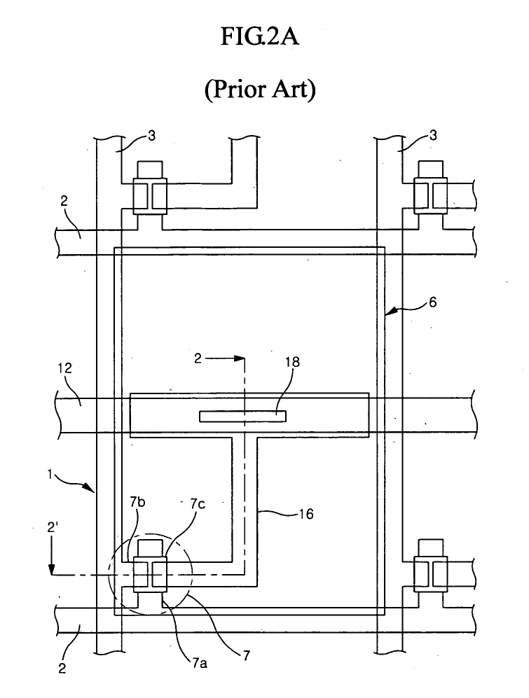

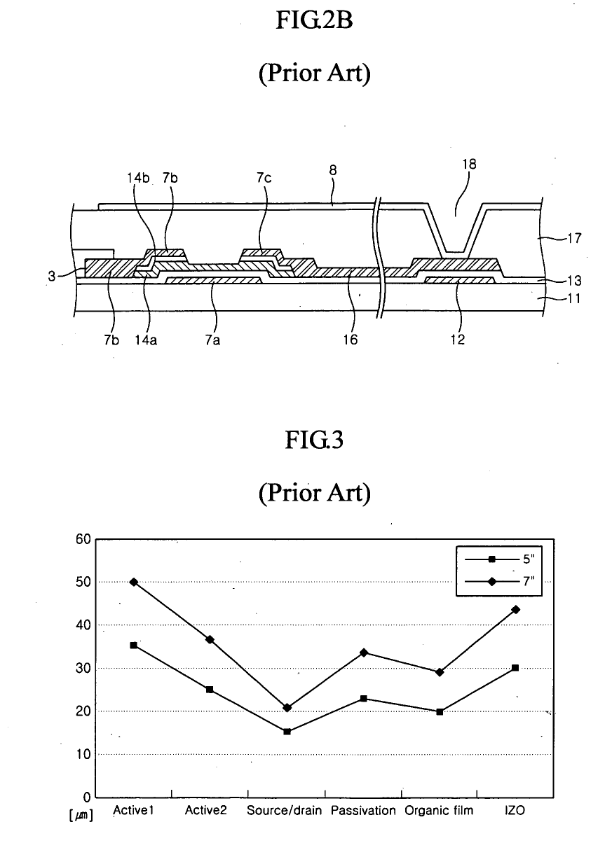

### DETAILED DESCRIPTION OF THE INVENTION

Hereinafter, preferred embodiments of the invention will be described in detail with reference to the accompanying drawings. In the drawings, the thickness of layers, films, and regions may be exaggerated for clarity. It will be understood that when an element such as a layer, film, region, or substrate is referred to as being “on” another element, it can be directly on the other element or intervening elements may also be present. Except as otherwise noted, like numerals refer to like elements throughout.

In general, the size of a unit pixel on a thin film transistor (“TFT”) substrate is automatically determined when size and resolution of a liquid crystal display (“LCD”) product are determined. Therefore, the design for a TFT array is composed of the steps of designing components of a unit pixel, i.e. a TFT, a pixel electrode, and a storage capacitor in consideration of the physical properties of a liquid crystal used and the fabricating process margin, and arranging the unit pixel as a matrix structure connected by gate lines and data lines. Important considerations during the design of the unit pixel of the TFT array include a structure of the TFT that determines the performance of the TFT, a W/L size, a structure and electrode size of the storage capacitor, arrangement of the pixel electrode in consideration of the intervals between signal lines and the black matrix overlap of a color filter substrate, a width and thickness of the gate line, a width and thickness of the data line, and so on.

Meanwhile, the present invention is directed to the design of the TFT array on a flexible substrate. Therefore, the misalignment due to the expansion or shrinkage of the flexible substrate during the fabricating process should be taken into account, in addition to the aforementioned considerations. Accordingly, the design of the exemplary embodiments of the TFT array described herein is focused on the TFT structure, particularly the width and structure of the data and gate lines, thereby satisfying the fabricating process margin due to an expansion or shrinkage of the flexible substrate.

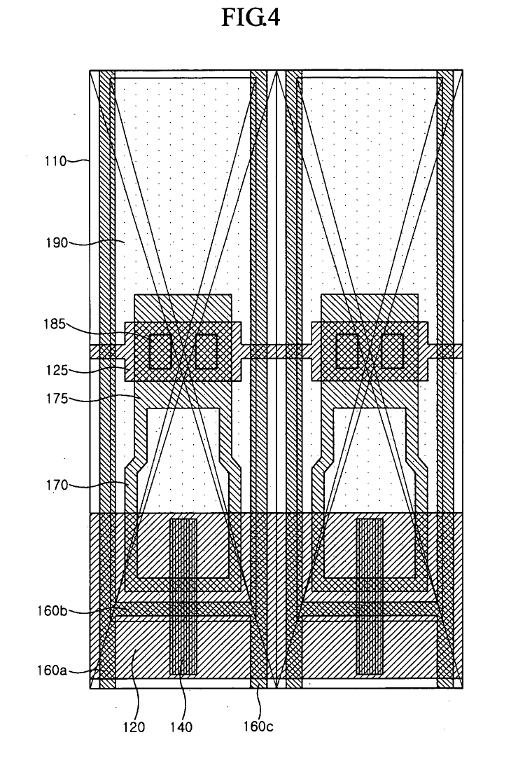

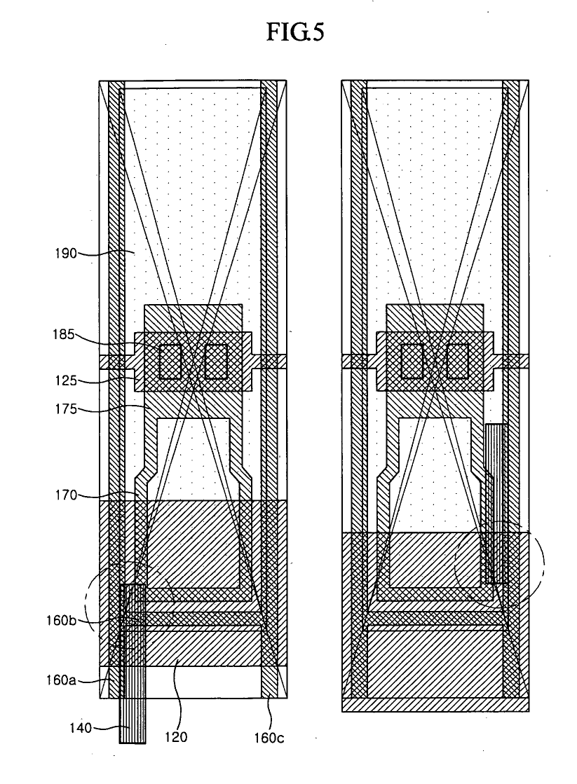

FIG. 4 is a plan view of a first exemplary embodiment of a TFT substrate of an LCD device according to the present invention, and FIG. 5 is a plan view illustrating a state where the maximum alignment occurs in the first exemplary embodiment of the TFT substrate according to the present invention.

FIG. 4 shows a case where there are no misalignments due to the expansion or shrinkage of the flexible substrate used in the TFT substrate during the fabricating process.

Referring to FIG. 4, the TFT substrate of the LCD device is configured in such a manner that a gate line 120 of a certain line width is formed in one direction, such as a first direction or a transverse direction, on a transparent insulating substrate 110. In these embodiments, a flexible substrate made of a plastic material or the like is used as the transparent insulating substrate 110. In this case, the line width of the gate line 120 is controlled by means of the maximum misalignment range according to the expansion rate or shrinkage rate of the transparent insulating substrate 110 during the fabricating process. That is, the line width of the gate line 120 is preferably larger than a line width of the data line 160, where a portion of the data line 160 is overlapped with the gate line 120.

A pair of first data lines 160a and 160c that are insulated from and intersected with the gate line 120 are arranged at both ends of the unit pixel at regular intervals. The pair of first data lines 160a and 160c may extend in a second direction, such as a longitudinal direction, that is substantially perpendicular to the first direction that the gate line 120 extends. Also, the pair of first data lines 160a and 160c may be parallel to each other.

In addition, the second data line 160b is formed in parallel with the gate line 120, and both ends of the second data line 160b are connected to the pair of first data lines 160a and 160c, respectively. That is, a first end of the second data line 160b may be connected to the data line 160a, and a second end of the second data line 160b may be connected to the data line 160c. The second data line 160b may be arranged substantially perpendicular with respect to the pair of fist data lines 160a and 160c. Therefore, according to this embodiment of the present invention, the data lines 160a to 160c are mutually connected and arranged in a ring shape, such as a closed loop over adjacent pixels, or such as a rectangular shape with an open top within each pixel. As a result, a signal voltage applied from an exterior source can be safely transferred, even if any one of the data lines becomes disconnected.

An active layer 140 intersects the data line 120, and is patterned in a rectangular shape with longer sides of the rectangular shape extending parallel to the pair of first data lines 160a and 160c. The active layer 140 is arranged between the pair of first data lines 160a and 160c. According to the illustrated embodiment of the present invention, the active layer 140 is described as a rectangular shape, but the present invention is not limited thereto, and other shapes are within the scope of these embodiments.

A drain electrode 170 is formed in parallel to and spaced apart from the data lines 160a to 160c by a predetermined interval. That is, the drain electrode 170 is also arranged in a rectangular shape with an open top, such as a U-shape, similar to the data lines 160a to 160c. In other words, the drain electrode 170 may include a first section extending adjacent to data line 160a and parallel with data lines 160a and 160c, a second section extending adjacent to data line 160b and parallel with data line 160b, and a third section extending adjacent to data line 160c and parallel with data lines 160a and 160c.

According to the aforementioned TFT structure, the TFT can be formed at an arbitrary position in the range of the gate line 120, even if a misalignment occurs by expansion or shrinkage of the transparent insulating substrate 110 during the fabricating process.

Meanwhile, a lower storage electrode 125 is arranged at a central portion of a pixel in parallel to the gate line 120, and an upper storage electrode 175 is formed over the lower storage electrode 125. The upper storage electrode 175 is formed by further extending a portion of the drain electrode 170. In other words, the upper storage electrode 175 is extended from the first and third sections of the drain electrode 170, in the second direction that the data lines 160a and 160c extend, so that the drain electrode 170 overlies the lower storage electrode 125.

A pixel electrode 190 is formed over the entire surface, or over substantially the entire surface, of the unit pixel and is electrically connected to the upper storage electrode 175 through a contact hole 185.

Referring to FIG. 5, a case where the maximum misalignment occurs in the first exemplary embodiment of the TFT substrate according to the present invention is illustrated.

According to the present invention, as shown in the left unit pixel of FIG. 5, the TFT is formed at the lower left end of the gate line 120, even though the misalignment occurs as the gate line 120 moves upward and the active layer 140 moves leftward and downward.

In addition, as shown in the right unit pixel of FIG. 5, the TFT is formed at the upper right end of the gate line, even though the misalignment occurs as the gate line 120 moves downward and the active layer 140 moves rightward and upward. As such, according to the unit pixel structure of the present invention, the TFT can be stably formed even though the maximum misalignment occurs in each layer.

Hereafter, a method of fabricating the first exemplary embodiment of the TFT substrate for an LCD device according to the present invention will be described.

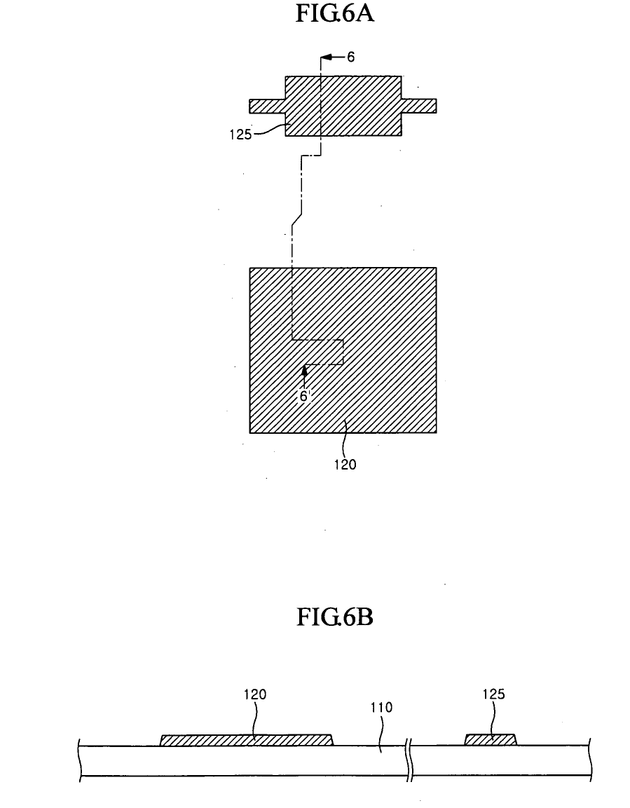

FIGS. 6A to 10B are plan views and sectional views showing in sequence a process of fabricating the first exemplary embodiment of the TFT substrate according to the present invention.

Referring to FIGS. 6A and 6B, a first conductive film (not shown) is formed on the transparent insulating substrate 110, and the lower storage electrode 125 and the gate line 120 with a certain line width are formed from the first conductive film by means of a photolithographic process using a first photoresist mask pattern (not shown). At this time, a flexible substrate made of a plastic material or the like may be used as the transparent insulating substrate 110.

More particularly, the first conductive film is formed on the transparent insulating substrate 110 by means of a vapor deposition method such as chemical vapor deposition (“CVD”), physical vapor deposition (“PVD”), or sputtering method. Preferably, the first conductive film is formed of at least one of chromium Cr, molybdenum-tungsten MoW, chromium/aluminum Cr/Al, copper Cu, aluminum (neodymium) Al(Nd), molybdenum/aluminum Mo/Al, molybdenum/aluminum (neodymium) Mo/Al(Nd) and chromium/aluminum (neodymium) Cr/Al(Nd). The first conductive film may be formed into a multi-layered film. Next, after the photoresist film is coated, the first photoresist mask pattern is formed by performing a lithography process using a first mask. The gate line 120 and the lower storage electrode 125 are formed, as shown in FIGS. 6A and 6B, by performing an etching process using the first photoresist mask pattern as an etching mask. Then, the first photoresist mask pattern is removed by performing a predetermined stripping process. The line width of the gate line 120 is formed larger than a line width of the data line 160a, 160b, 160c to be described later in detail, and preferably, the line width of the gate line 120 is controlled in consideration of the maximum misalignment margin according to the expansion or shrinkage rate of the transparent substrate 110. For example, the line width of the gate line 120 may be selected and formed in view of an expected or anticipated possible maximum misalignment margin, so that any actual misalignment may be within the margins and a TFT will still be formed within each pixel.

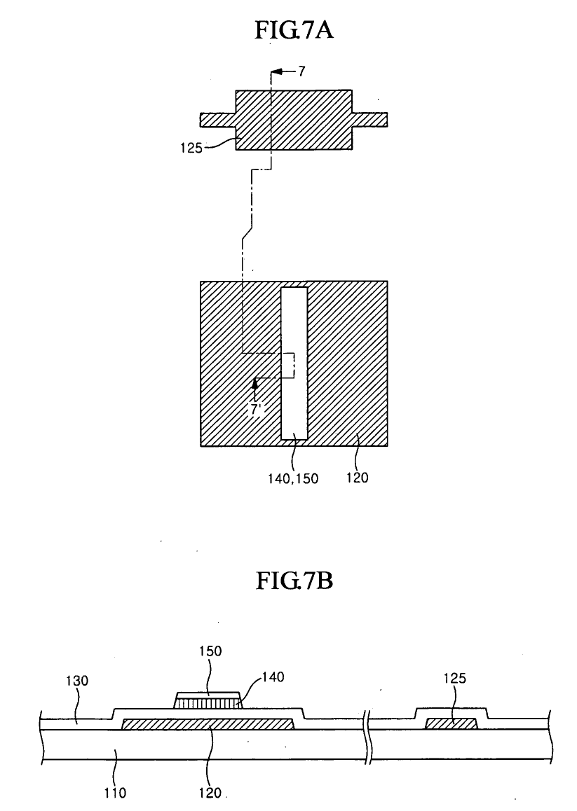

Referring to FIGS. 7A and 7B, a gate insulating film 130, and layers for eventually forming an active layer 140 and an ohmic contact layer 150 are sequentially formed on the entire structure shown in FIG. 6. Then, an active area of the TFT is formed by means of an etching process using a second photoresist mask pattern (not shown).

The gate insulating film 130 is formed on the entire substrate, including the transparent insulating substrate 110, the gate lines 120, and the lower storage electrodes 125, by means of a vapor deposition method such as plasma enhanced chemical vapor deposition (“PECVD”) or sputtering method. In this case, an inorganic insulating material including silicon oxide or silicon nitride is preferably used as the gate insulating film 130, although other suitable materials are within the scope of these embodiments. The layers for forming the active layer 140 and the ohmic contact layer 150 are sequentially formed on the gate insulating film 130 by means of the aforementioned vapor deposition method. The layer for forming the active layer 140 is formed of amorphous silicon a-Si, and the layer for forming the ohmic contact layer 150 is formed of a silicide or amorphous silicon doped with high concentration of N-type impurities, where an impurity is a substance that is incorporated into a semiconductor material and provide free electrons (N-type impurity) or holes (P-type impurity). Then, the photoresist is coated on the layer for forming the ohmic contact layer 150, and the second photoresist mask pattern is formed by means of a photolithography process using a second mask. An active area is formed on the gate line 120 by removing the layers for forming the ohmic contact layer 150 and the active layer 140 through an etching process using the second photoresist mask pattern as an etching mask and the gate insulating film 130 as an etching stopper film. Then, the remaining portion of the second photoresist mask pattern is removed by means of a stripping process.

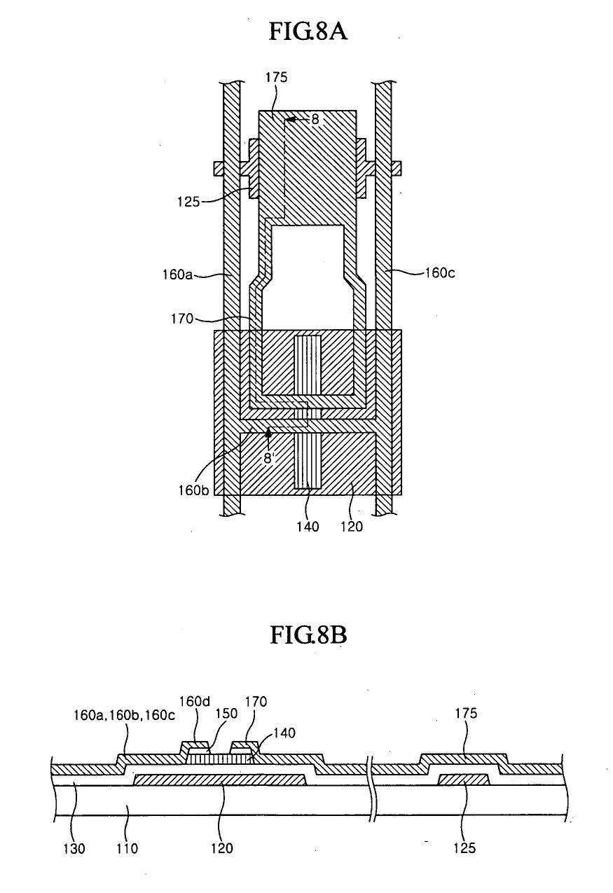

Referring to FIGS. 8A and 8B, a second conductive film is formed on the entire structure shown in FIGS. 7A and 7B with the active area of the TFT formed therein. Then, the data lines 160a to 160c, the drain electrode 170, and the upper storage electrode 175 are formed by means of an etching process using a third photoresist mask pattern (not shown).

The second conductive film is formed on the entire substrate shown in FIGS. 7A and 7B by means of a vapor deposition method such as CVD, PVD or sputtering method. In this case, the second conductive film is preferably formed of single-layered or multi-layered metal using at least one of molybdenum Mo, aluminum Al, chromium Cr and titanium Ti. Alternatively, the second conductive film may be formed of the same material as the first conductive film. Preferably, the second conductive film has a thickness of 1,500 Å to 3,000 Å through the vapor deposition. Then, a photoresist film is applied to the second conductive film, and the third photoresist mask pattern is formed using a lithography process using a mask. The second conductive film is etched by means of an etching process using the third photoresist mask pattern as an etching mask and the third photoresist mask pattern is then removed. Thereafter, the layer for forming the ohmic contact layer 150 on the exposed area between the second conductive films is removed by means of an etching process using the etched second conductive film as an etching mask to thereby form a channel composed of the active layer 140 between the data line 160b and the drain electrode 170, as shown in FIG. 8B, and then to form the drain electrode 170 and the upper storage electrode 175. That is, the source electrode 160d and the drain electrode 170 of the TFT are formed on the active layer 140 by removing portions of the layer for forming the ohmic contact layer 150 and the second conductive film. Here, the active layer 140 between the second data line 160b and the drain electrode 170 may be exposed by removing a portion of the layer for forming the ohmic contact layer 150 without removing the third photoresist mask pattern.

Through the aforementioned processes, the data lines 160a, 160b, and 160c are mutually connected and patterned in a ring shape. The active layer 140 intersects the gate line 120 and is patterned in parallel to the pair of first data lines 160a and 160c in a rectangular shape such that the active layer is arranged between the pair of first data lines 160a, 160b. In addition, each section of the drain electrode 170 is formed in parallel with the data lines 160a to 160c, respectively, and is spaced apart therefrom by a certain interval and sections of the drain electrode 170 extend toward the upper storage electrode 175.

Through the aforementioned processes, the TFT within each pixel of the LCD device can be stably formed at the intersection between the gate line 120 and the data line 160, even if a misalignment in the data line 160, the source electrode 160d of the TFT and the drain electrode 170 with respect to the gate line 120 occurs as a result of the expansion or shrinkage of the insulating substrate 110 that may occur after the gate line 120 has been formed.

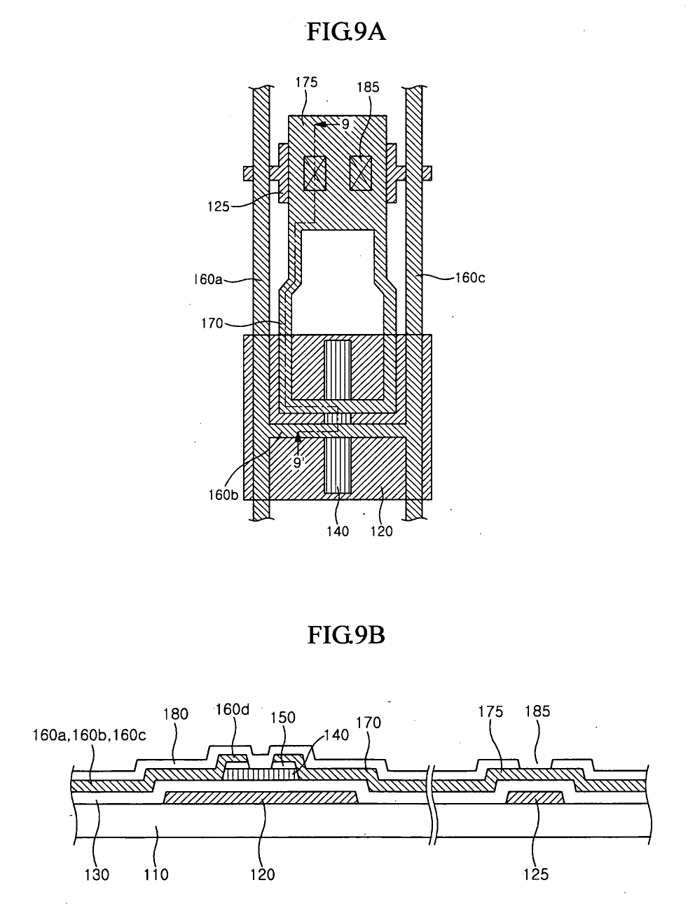

Referring to FIGS. 9A and 9B, a protective film 180 is formed on the transparent insulating substrate 110 with the drain electrode 170 and upper storage electrode 175 formed in part thereon, and the contact hole 185 is formed by removing a portion of the protective film 180 by means of an etching process using a fourth photoresist mask pattern.

That is, the protective film 180 is formed on the entire structure shown in FIGS. 8A and, 8B by means of any of a variety of vapor deposition methods. The protective film 180 is preferably formed of the same insulating material as the gate insulating film 130. In addition, the protective film 180 may be formed to have a multi-layered structure. For example, the protective film can be formed of two layers of inorganic and organic protective films. After coating a photoresist film on the protective film 180, the fourth photoresist mask pattern (not shown) for exposing a contact area is formed by means of a photolithography process using a mask. Then, a plurality of contact holes 185 for exposing a portion of each of the upper storage electrodes 175 is formed by means of an etching process using the fourth photoresist mask pattern as an etching mask. The remaining portion of the fourth photoresist mask pattern is removed through a stripping process.

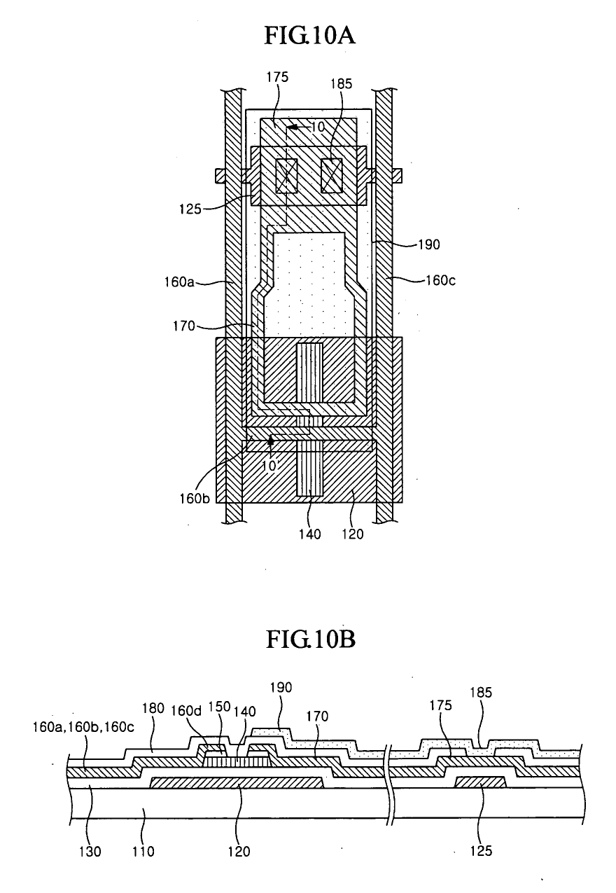

Referring to FIGS. 10A and 10B, a third conductive film is formed on the patterned protective film 180, and the pixel electrode 190, a gate pad, and a data pad are formed by patterning the third conductive film using a fifth photoresist mask pattern (not shown). Here, the third conductive film is preferably formed of a transparent conductive film including, but not limited to, Indium Tin Oxide (“ITO”) or Indium Zinc Oxide (“IZO”).

First, the third conductive film is formed on the entire structure shown in FIGS. 9A and 9B using a predetermined vapor deposition method, and the photoresist film is coated. Then, the fifth photoresist mask pattern is formed using the lithography process using a mask. The other areas, except predetermined areas such as the pixel electrode 190, gate pad areas, and data pad areas, are exposed by means of the fifth photoresist mask pattern. Next, the exposed area of the third conductive film is removed by means of an etching process using the fifth photoresist mask pattern as an etching mask, and the fifth photoresist mask pattern is then removed by means of a desired stripping process. Finally, the gate pad, the data pad, and the pixel electrode 190 are formed. While a pixel electrode 190 may be included within each pixel area of the LCD device, a gate pad and a data pad may be formed at an end of each gate line and data line, as will be further described below.

Although it has been described in the aforementioned method that the five masks are employed to fabricate the TFT substrate, the present invention is not limited thereto. In the method of fabricating the TFT substrate according to the present invention, a variety of masking processes using more than or less than five masks may be modified.

Furthermore, a common electrode substrate is manufactured by sequentially forming a black matrix, a color filter, an overcoat film, a transparent common electrode and an alignment film on a transparent insulating substrate. In this case, the transparent insulating substrate of the common electrode substrate is formed of the same material as the transparent insulating substrate 110 of the TFT substrate. That is, if a flexible substrate made of a plastic material or the like has been used as the transparent insulating substrate 110 of the TFT substrate, then the transparent insulating substrate of the common electrode substrate is also formed of a flexible substrate made of a plastic material or the like.

Then, the TFT substrate and the common electrode substrate, which have been fabricated in the above way, are bonded to each other with a spacer such as a peripheral seal interposed between the substrates. Next, a liquid crystal material is injected into a space defined by the spacer using a vacuum injection method, or other method, to thereby fabricate an LCD device.

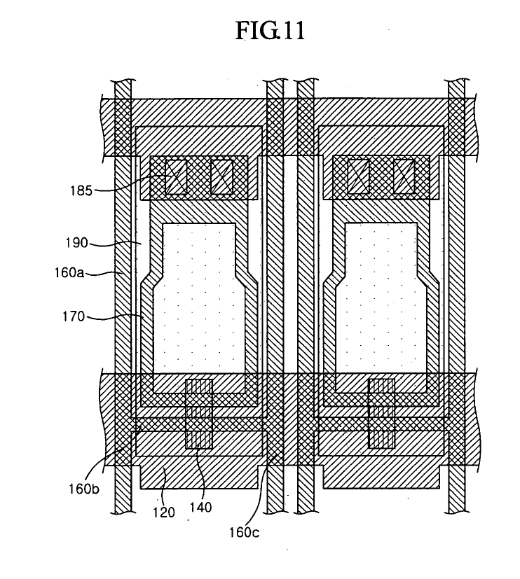

FIG. 11 is a plan view of a second exemplary embodiment of a TFT substrate of an LCD device according to the present invention.

The second exemplary embodiment of the present invention is different from the first exemplary embodiment in that a portion of adjacent gate lines 120 is used as a storage electrode line instead of employing a separate storage electrode line to form a lower storage electrode 125 there from. Other components of the second exemplary embodiment are substantially the same as those of the first exemplary embodiment. Therefore, the description of the same components will be omitted herein, and only the different components will be explained hereinafter.

The gate line 120 with a predetermined line width is formed on the transparent insulating substrate 110 in one direction, such as a first direction or transverse direction. In this case, the gate line 120 also protrudes toward the neighboring pixel area, so that the protruding portion is used as a storage electrode line for the neighboring pixel. That is, the lower storage electrode for each pixel is formed from a protruding portion of a gate line 120 from a neighboring pixel.

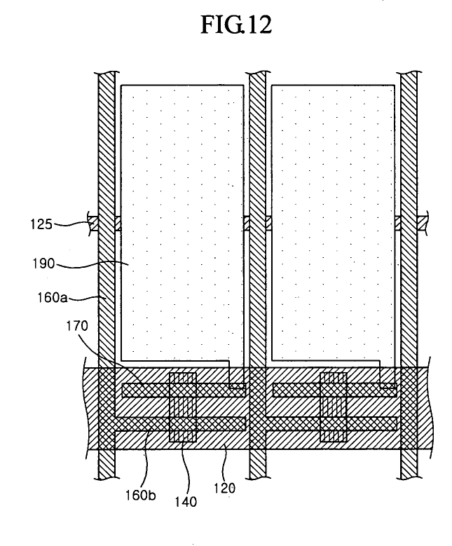

FIG. 12 is a plan view of a third exemplary embodiment of a TFT substrate of an LCD device according to the present invention.

Referring to FIG. 12, the TFT substrate of the LCD device is manufactured by allowing the gate line 120 to be formed on the transparent insulating substrate 110 in one direction, such as a first direction or a transverse direction. In this case, the line width of the gate line 120 is determined by the maximum misalignment range according to the expansion or shrinkage rate of the transparent insulating substrate 110 that may occur during the fabricating process.

The first data line 160a is arranged in such a manner that it is insulated from and intersected with the gate line 120. The first data line 160a may be extended in a second direction, such as a longitudinal direction, that is substantially perpendicular to the gate line 120. The second data line 160b is formed in parallel with the gate line 120 to intersect the active layer 140. One end of the second data line 160b is connected to the first data line 160a. The drain electrode 170 is formed in parallel with and spaced apart from the second data line 160b by a desired distance. In this case, the second data line 160b and the drain electrode 170 are preferably formed in such a manner that they are each at least partially overlapped with an area where the gate line 120 is formed.

The active layer 140, having a rectangular shape, intersects the gate line 120 and is arranged lengthwise in parallel with the first data line 160a. Although it has been illustrated in this embodiment that the active layer 140 is shaped as a rectangle, the present invention is not limited thereto.

Meanwhile, the storage electrode line 125 is arranged parallel to the gate line 120 at a central portion of the pixel. The pixel electrode 190 is formed over the entire area, or substantially the entire area, of the unit pixel and is electrically connected to the drain electrode 170 through a contact hole (not shown).

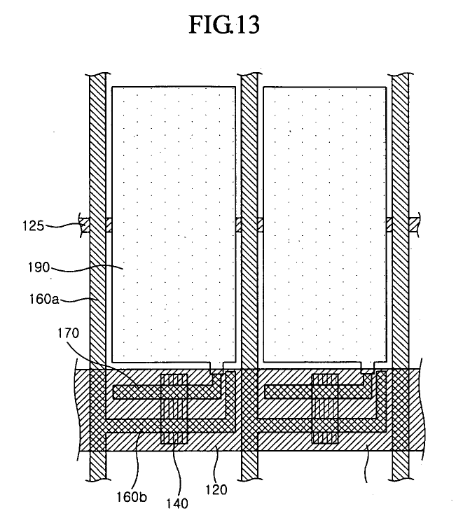

FIG. 13 is a plan view of a fourth exemplary embodiment of a TFT substrate of an LCD device according to the present invention.

The second data line and the drain electrode of the fourth exemplary embodiment are different from those of the third exemplary embodiment in view of their shapes, whereas the other components are substantially the same in the two embodiments. Therefore, the description of the same components is omitted herein, and only the different components will be explained hereinafter.

Referring to FIG. 13, the second data line 160b is bent in such a manner that a portion thereof is in parallel with the gate line 120 while the other portion thereof is parallel to the first data line 160a. In addition, the drain electrode 170 is formed in the same shape as the second data line 160b in a state where the drain electrode 170 and the second data line 160b are spaced apart by a certain interval. That is, the second data line 160b and the drain electrode 170 are each formed in an L shape, a right angle shape, etc.

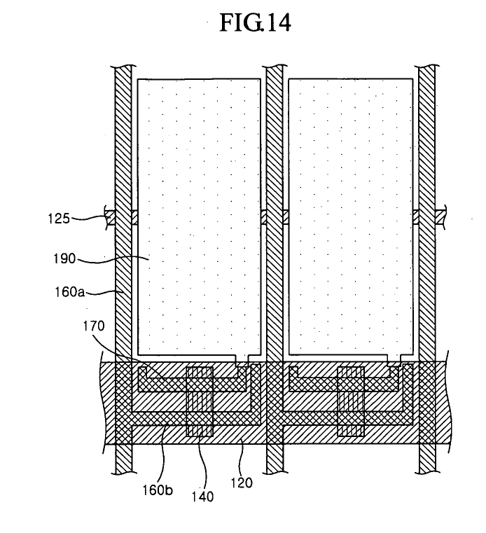

FIG. 14 is a plan view of a fifth exemplary embodiment of a TFT substrate of an LCD device according to the present invention.

The second data line 160b and the drain electrode 170 of the fifth exemplary embodiment are different from those of the third and fourth exemplary embodiments in view of their shapes, but the other components are the same as one another. Therefore, the description of the same components is omitted herein, and only the different components will be explained hereinafter.

The second data line 160b is bent in such a manner that a portion thereof is in parallel to the gate line 120 while the other portion is in parallel to the first data line 160a. That is, the second data line 160b is formed in an L shape, or a right angle. On the other hand, the drain electrode 170 is bent in such a manner that a portion thereof is in parallel to the second data line 160b while the other portions thereof, including a portion adjacent the first data line 160a and a portion adjacent the portion of the second data line 160b that is parallel to the first data line 160a, are in parallel to the first data line 160a.

Although a variety of the second data lines 160b and drain electrodes 170 have been illustrated in the third to fifth exemplary embodiments, they are merely illustrative examples of the present invention. That is, the present invention is not limited thereto.

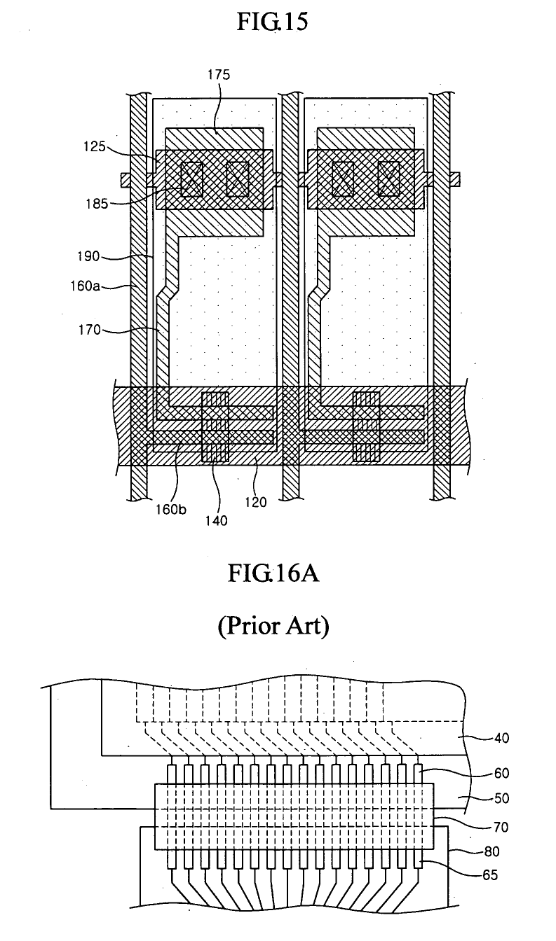

FIG. 15 is a plan view of a sixth exemplary embodiment of a TFT substrate of an LCD device according to the present invention.

The sixth exemplary embodiment is similar to the third exemplary embodiment in view of the structures of the TFT substrates, but is different from the third exemplary embodiment in that a portion of the drain electrode 170 extends over the top of the lower storage electrode 125 to thereby form the upper storage electrode 175.

Referring to FIG. 15, the TFT substrate of the LCD device is manufactured by allowing the gate line 120 with a desired line width to be formed on the transparent insulating substrate 110 in one direction, such as a first direction or a transverse direction, and arranging the first data line 160a to be insulated from and intersected with the gate line 120. The first data line 160a may extend in a second direction substantially perpendicular with the first direction. The second data line 160b is formed in parallel to the gate line 120 in such a way as to intersect the active layer 140, and one end of the second data line 160b is connected to the first data line 160a. One portion of the drain electrode 170 is formed parallel to the second data line 160b while being spaced apart therefrom by a desired interval. At this time, the second data line 160b and the drain electrode 170 are each preferably formed within an area where the gate line 120 is formed.

The active layer 140 intersects the gate line 120 and is arranged parallel to the first data line 160a, with the active layer 140 having a rectangular shape. Although it has been illustrated in this embodiment that the active layer 140 is formed in a rectangular shape, the present invention is not limited thereto.

As described above, a variety of the second data lines 160b and drain electrodes 170 may be formed in addition to the shape of the second data line 160b and drain electrode 170 illustrated in this embodiment.

Meanwhile, the lower storage electrode 125 is formed at a central portion of the pixel in parallel to the gate line 120. A portion of the drain electrode 170 extends toward the lower storage electrode 125 such that the upper storage electrode 175 can be formed on the top of and over the lower storage electrode 125. The pixel electrode 190 is formed over the entire surface, or substantially the entire surface, of the unit pixel and is electrically connected to the upper storage electrode 175 through the contact hole 185.

According to the present invention, even though the TFT substrate and the LCD device using the same are formed on the flexible substrate, a process margin enough to overcome the misalignment due to the expansion or shrinkage of the flexible substrate can be ensured. That is, even if misalignments occur between elements of the TFT substrate, the TFTs are still maintained intact, where each TFT includes an active layer, such as a semiconductor layer, a gate electrode as a part of the gate line, a source electrode as part of the data line, and a drain electrode connected to the pixel electrode. As shown in FIG. 5, the exact location of the source electrode and the drain electrode may vary with respect to a gate electrode of the gate line 120 depending on a shifted location of the active layer 140 with respect to the gate line 120 and with respect to the data line 160 and drain electrode 170. However, a TFT is still maintained in each instance of misalignment between layers of the TFT substrate, and therefore gate signals and data signals delivered from drivers to each TFT still effectively deliver signals to the pixel electrodes connected thereto.

Hereafter, a pad structure prepared for the misalignment due to the expansion or shrinkage of the flexible substrate will be described.

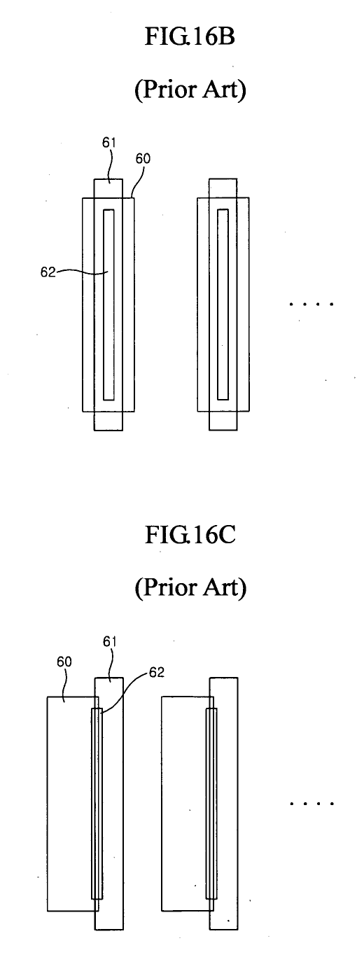

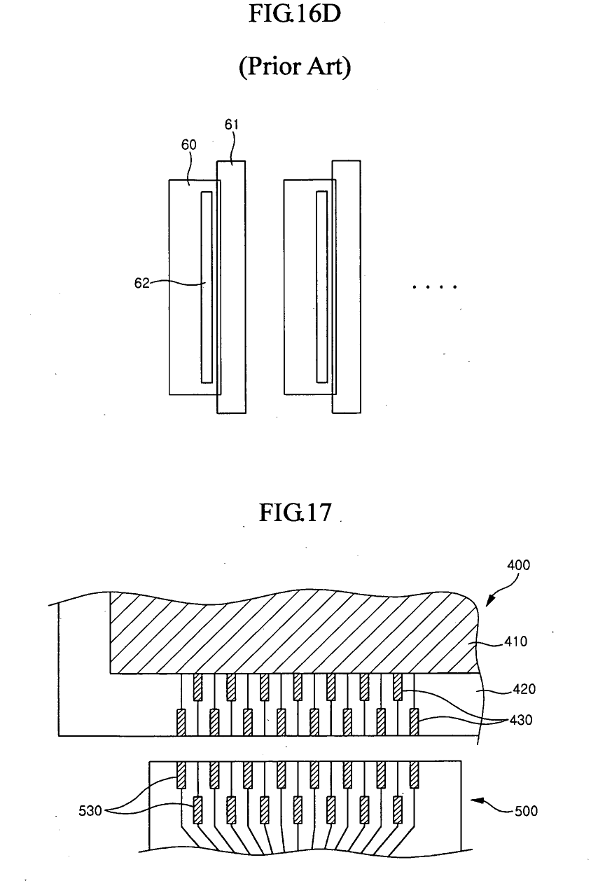

First, FIG. 16A is a partial plan view showing a pad structure of the conventional LCD device. Referring to FIG. 16A, the LCD device having a combined common electrode substrate 40 and TFT substrate 50 is spaced apart from a tape carrier package (“TCP”) 80 equipped with a driver integrated circuit (“IC”) (not shown) by a certain interval. The LCD device is provided, at a portion adjacent the TCP 80, with pads 60 for receiving signals applied by the driver IC mounted in the TCP 80. In the same manner, pads 65 having the same shape and number as the pads 60 are formed at a portion of the TCP 80 adjacent to the LCD device. Therefore, an electrically insulating tape 70 with a plurality of conductive leads is attached on both the pads 60 of the LCD device and the pads 65 of the TCP 80, so that the LCD device and TCP 80 are electrically connected with each other.

FIGS. 16B to 16D are enlarged views of portions of the pads formed on the TCP and the LCD device using the flexible substrate. FIG. 16B shows a pad structure of the LCD device ideally formed when no misalignments occur, whereas FIGS. 16C and 16D show pad structures of the LCD device when the misalignment occurs. FIGS. 16C and 16D show some examples in which the contact hole 62 for connecting the signal line 61, e.g. the gate line or data line, to the pad 60 is formed outside of the pad 60 or signal line 61 due to the expansion or shrinkage of the plastic substrate so that they are not properly brought into contact with each other or not at all. As such, the LCD device using the flexible substrate may involve the misalignment not only in the pixel area but also in the I/O pad connected to the pixel area due to the expansion or shrinkage of the flexible substrate. Therefore, improvement of the pad structure is required to fabricate an LCD device capable of ensuring a sufficient process margin in spite of the expansion or shrinkage of the flexible substrate.

FIG. 17 is a plan view of an exemplary embodiment of a pad structure of the LCD device according to the present invention.

Referring to FIG. 17, the TFT substrate 420 and the common electrode substrate 410 using the flexible substrate made of a plastic material or the like are formed within the LCD device 400 to be opposite to each other, and the liquid crystal (not shown) is inserted between the two substrates 410 and 420. The LCD device 400 and the TCP 500 mounted with the driver IC (not shown) are arranged at a certain interval.

A plurality of pads 430 for receiving driving signals applied by the driver IC mounted on the TCP 500 are formed at an end of the TFT substrate 420 of the LCD device 400. Further, a plurality of pads 530 having the same shape and number as those of the pads 430 of the LCD device 400 are formed at an end of the TCP 500. Since the pads 430 of the LCD device 400 have the same structure as the pads 530 of the TCP 500, only the pads 430 of the LCD device 400 will be described hereinafter.

The pads 430 of the LCD device 400 are spaced apart from one another at regular intervals and arranged in two rows. In this case, two adjacent pads 430 are arranged in different rows, and alternating pads 430 are arranged in different rows. That is, the whole pad structure is configured in a zigzag form, with a first row of pads 430 being arranged closer to the TCP 500 and a first periphery of the LCD device 400 than a second row of pads 430. In this embodiment, the pads 430 are illustrated as being arranged in two rows, but this is merely illustrative. That is, the pads 430 may be arranged in more than two rows.

According to the aforementioned pad structure, the (n+1)-th pad next to the n-th pad is arranged in a different row from the n-th pad, and the (n+2)-th pad is arranged in the same row as the n-th pad, and so on. Therefore, the above pad structure will actually have a pitch twice as great as that of the line-shaped pad structure even though the former has the same pitch as that of the latter. As a result, as compared with the conventional line-shaped pad structure, the line width of the pad 430 can be increased and the interval between the pads 430 can be reduced. Accordingly, a margin sufficient enough to overcome misalignment due to the expansion or shrinkage of the plastic substrate can be ensured.

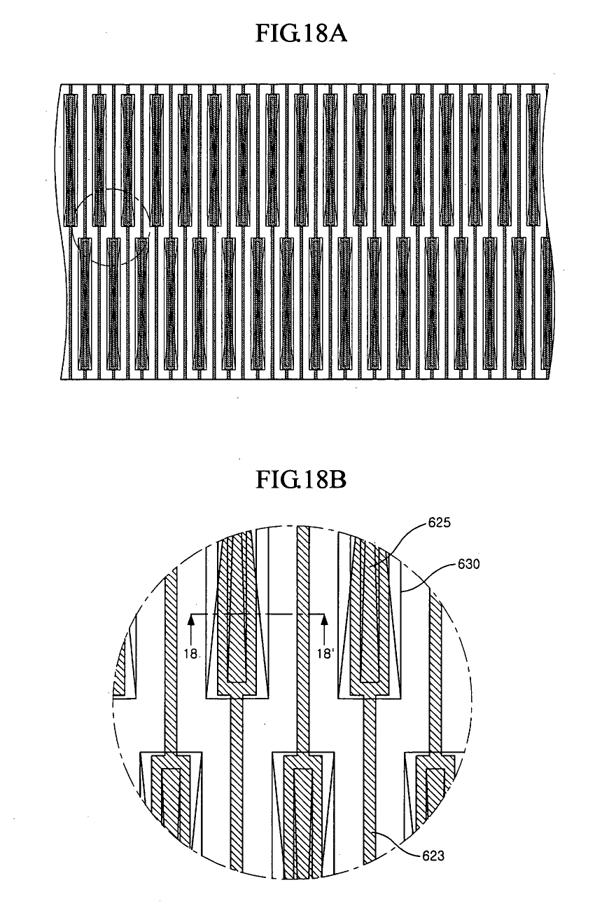

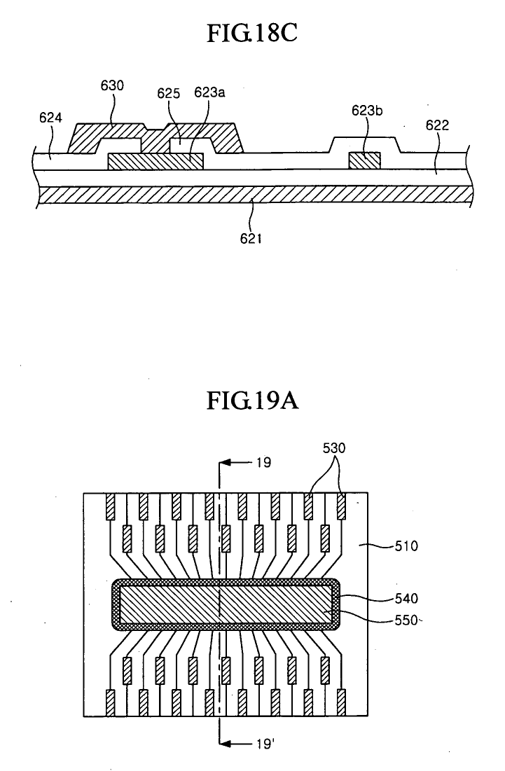

FIGS. 18A and 18B are enlarged views of an exemplary embodiment of the pad structure of the LCD device according to the present invention, in which the pad structure is formed at an end of the data line of the LCD device. FIG. 18C is a sectional view taken along line 18-18′ in FIG. 18B.

Referring to FIGS. 18A and 18B, the pads 630 are formed in two rows at an end of each data line 623 of the LCD device. The pads 630 are arranged in such a manner that an arbitrary pad 630 is formed in a first row, another pad 630 adjacent to the arbitrary pad 630 is formed in a second row, the next pad 630 is formed again in the first row, etc.

The line width of the data line 623 at a portion where the pad 630 is formed becomes larger than a line width of a portion of the data line 623 where the pad 630 is not formed, and the width of the pad 630 becomes larger than that of the data line 623. Further, in this embodiment, the width of the contact hole 625 for connecting the data line 623 to the pad 630 is much larger than that of the contact hole, e.g. contact hole 62 of FIGS. 16B to 16D, used in the conventional line-shaped pad structure, and preferably the width of the contact hole 625 becomes almost the same as the width of the data line 623 at the portion where the pad 630 is not formed.

Referring to FIG. 18C, an insulating film 622 is formed on the plastic or other flexible substrate 621, and the data lines 623, including the data lines 623a at the portions where the pads 630 are formed and the data lines 623b at the portions where the pads 630 are not formed, are formed on the insulating film 622. Thereafter, a protective film 624 is formed on the data lines 623, the contact holes 625 are formed on the data lines 623a, and the pads 630 are also then formed. The data lines 623b are data lines adjacent to the data lines 623a so that the width of the data lines 623a on which the pads 630 are formed is larger than the width of the data lines 623b where no pad 630 is formed. Although it has been described in this embodiment that the pads 630 are formed at ends of the data lines 623, the pads 630 may also be formed at ends of the gate lines.

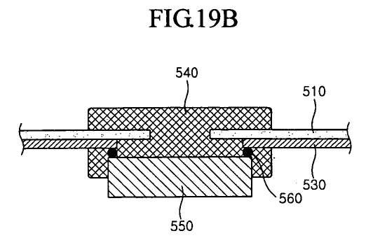

FIG. 19A shows a TCP structure corresponding to the exemplary pad structure of the LCD device according to the present invention, and FIG. 19B is a sectional view of the TCP taken along line 19-19′ in FIG. 19A.

Referring to FIGS. 19A and 19B, the TCP includes a flexible film 510, pads 530, a protective film 540, an LDI chip 550, and a bump 560. The flexible film 510 is generally formed of a polyimide film, and the LDI chip 550 is mounted on the flexible film 510 by means of the bump 560. The bump 560 connects the LDI chip 550 mounted on the TCP to electric wiring of the TCP. In addition, one end of each pad 530 is connected to the pad, e.g. pad 630 of FIGS. 18A to 18C, of the LCD device, and the other end of each pad 530 is connected to a PCB with a driver unit mounted thereon.

The structure of the pad 530 is the same as the structure of the pads, e.g. pads 630, of the LCD device. That is, the pads 530 of the TCP are spaced apart from one another by regular intervals and arranged in two rows. In this case, pads 530 adjacent to each other are arranged in different rows. Therefore, the whole pad structure is configured in a zigzag form. In this embodiment, only the pads 530 arranged in two rows are illustrated, but this is merely illustrative. That is, the pads 530 may be arranged in more than two rows.

An anisotropic conductive film is attached on the pad, e.g. pad 630 of the LCD device, and the TCP mounted with the LDI chip 550 is aligned and temporarily pressed on the above-described LCD device. Then, the pads 630 of the LCD device and the pads 530 of the TCP are connected to each other by means of the thermo-compression bonding.

In this embodiment, only the TCP is described as an example. However, this is only illustrative. The present invention can be applied to other pad structures using Chip On Film (“COF”) technology in which a more flexible material than the TCP is used and can be freely bent over 90 degrees at any positions.

The previous embodiments of the present invention illustrate mainly the LCD device, but the TFT substrate and pad structures of the present invention are not limited to the aforementioned LCD device. In addition to the LCD device, the present invention can be applied to other display devices such as an organic light emitting diode (“OLED”) display device using a principle that a light emitting element made of a semi-conductive organic material or conjugated polymer is inserted between two electrodes to which voltage is applied to flow electric current through the light emitting element to thereby emit light, or a PDP that reproduces color images from self-luminescence due to ultraviolet rays generated by arranging a plurality of small cells between two substrates and causing a gas (neon and argon) to be discharged between two electrodes (positive and negative).

In addition, although it has been described in the embodiments of the present invention that the flexible substrate is used as the transparent insulating substrate, the present invention is not limited thereto. Furthermore, the plastic substrate is illustrated as an example of the flexible substrate, but substrates made of other materials may be employed herein.

According to the present invention so configured, even when a maximum possible misalignment occurs due to the size change of the transparent insulating substrate during the process of fabricating the display device, the TFT can still be formed in a certain area of the unit pixel and a data line with a predetermined pattern can be formed in the unit pixel. Therefore, the disconnection of the data line can also be prevented.

Further, since the pad structure connected to the external circuit is improved, the pad that has been properly brought into contact with the data or gate line can be formed even if a misalignment occurs.

In addition, the LCD device to which the pad structure and unit pixel structure according to the present invention is applied can ensure a sufficient process margin against the expansion or shrinkage of the substrate.

Although the structure and operation of the TFT substrate and the method of fabricating the same according to the present invention have been illustrated and described in connection with the preferred embodiment, it is only for illustrative purposes. It will be readily understood by those skilled in the art that various modifications and changes can be made thereto without departing from the spirit and scope of the present invention defined by the appended claims. Moreover, the use of the terms first, second, etc. do not denote any order or importance, but rather the terms first, second, etc. are used to distinguish one element from another. Furthermore, the use of the terms a, an, etc. do not denote a limitation of quantity, but rather denote the presence of at least one of the referenced item.

What is claimed is:

1. A thin film transistor substrate, comprising:
a gate line formed on a base substrate;
a data line formed within the thin film transistor substrate and insulated from the gate line; and
a thin film transistor formed at an intersection between the gate line and the data line,
wherein a line width of the gate line is at least greater than a line width of the data line, the data line including a first data line insulated from and intersected with the gate line and a second data line intersecting the first data line and having an end electrically connected to the first data line, and a drain electrode of the thin film transistor spaced apart from the data line by a predetermined interval.

2. The thin film transistor substrate as claimed in claim 1, wherein the thin film transistor includes an active layer, and location of the active layer with respect to the gate and data lines determines location of the gate electrode and source electrode, respectively.

3. The thin film transistor substrate as claimed in claim 1, wherein the second data line is formed in parallel to the gate line.

4. The thin film transistor substrate as claimed in claim 3, wherein the second data line is formed completely over the gate line.

5. The thin film transistor substrate as claimed in claim 1, wherein the drain electrode is formed in parallel to the second data line.

6. The thin film transistor substrate as claimed in claim 1, wherein the second data line is formed such that a first portion thereof is parallel to the gate line and a second portion thereof is parallel to the first data line.

7. The thin film transistor substrate as claimed in claim 6, wherein the drain electrode includes a first section formed in parallel to the first portion of the second data line and a second section formed in parallel to the second portion of the second data line.

8. The thin film transistor substrate as claimed in claim 6, wherein the drain electrode includes a first section parallel to the first data line and a second section parallel to the second data line.

9. The thin film transistor substrate as claimed in claim 8, wherein the drain electrode includes a third section extending from the second section and formed in parallel to the first data line.

10. The thin film transistor substrate as claimed in claim 9, further comprising a storage electrode connected to the first and third sections of the drain electrode.

11. The thin film transistor substrate as claimed in claim 1, wherein the line width of the gate line is dependent on an expansion or shrinkage rate of the base substrate.

12. The thin film transistor substrate as claimed in claim 1, further comprising a first storage electrode.

13. The thin film transistor substrate as claimed in claim 12, wherein the first storage electrode is formed from a protrusion of a gate line from an adjacent pixel of the thin film transistor substrate.

14. The thin film transistor substrate as claimed in claim 12, wherein the first storage electrode is disposed in parallel to and spaced apart from the gate line by a predetermined interval.

15. The thin film transistor substrate as claimed in claim 14, further comprising a second storage electrode electrically connected to the drain electrode and formed on the first storage electrode.

16. The thin film transistor substrate as claimed in claim 15, further comprising a pixel electrode connected to the second storage electrode via a contact hole.

17. The thin film transistor substrate as claimed in claim 1, further comprising a pixel electrode connected to the drain electrode via a contact hole.

18. The thin film transistor substrate as claimed in claim 1, wherein the base substrate is a flexible substrate.

19. The thin film transistor substrate as claimed in claim 18, wherein the base substrate is made of a plastic material.

20. A display device comprising:
a thin film transistor substrate including:
a gate line formed on a base substrate;
a data line formed within the thin film transistor substrate and insulated from the gate line; and
a thin film transistor formed at an intersection between the gate line and the data line,
wherein a line width of the gate line is at least greater than a line width of the data line, the data line including a first data line insulated from and intersected with the gate line and a second data line intersecting the first data line and having an end electrically connected to the first data line, and a drain electrode of the thin film transistor spaced apart from the data line by a predetermined interval.

21. A thin film transistor substrate, comprising:
a gate line formed on a base substrate;
a data line formed within the thin film transistor substrate and insulated from the gate line; and
a thin film transistor formed at an intersection between the gate line and the data line,
wherein a line width of the gate line is at least greater than a line width of the data line, the data line including a pair of first data lines insulated from and intersected with the gate line and arranged in parallel to each other at a predetermined interval and a second data line electrically connected to the pair of first data lines, and a drain electrode of the thin film transistor spaced apart from the data line by a predetermined interval.

22. The thin film transistor substrate as claimed in claim 21, wherein the drain electrode includes sections extending parallel to the pair of first data lines and the second data line.

23. The thin film transistor substrate as claimed in claim 21, wherein the line width of the gate line is dependent on the expansion or shrinkage rate of the base substrate.

24. The thin film transistor substrate as claimed in claim 21, further comprising a first storage electrode.

25. The thin film transistor substrate as claimed in claim 24, wherein the first storage electrode is disposed in parallel to and spaced apart from the gate line by a predetermined interval.

26. The thin film transistor substrate as claimed in claim 24, further comprising a second storage electrode electrically connected to the drain electrode and formed on the first storage electrode.

27. The thin film transistor substrate as claimed in claim 26, further comprising a pixel electrode connected to the second storage electrode via a contact hole.

28. The thin film transistor substrate as claimed in claim 21, further comprising a pixel electrode connected to the drain electrode via a contact hole.

29. The thin film transistor substrate as claimed in claim 21, wherein the base substrate is a flexible substrate.

30. The thin film transistor substrate as claimed in claim 29, wherein the base substrate is made of a plastic material.

31. A display device comprising:
a thin film transistor substrate including
a gate line formed on a base substrate;
a data line formed within the thin film transistor substrate and insulated from the gate line; and
a thin film transistor formed at an intersection between the gate line and the data line,
wherein a line width of the gate line is at least greater than a line width of the data line, the data line including a pair of first data lines insulated from and intersected with the gate line and arranged in parallel to each other at a predetermined interval and a second data line electrically connected to the pair of first data lines, and a drain electrode of the thin film transistor spaced apart from the data line by a predetermined interval.

32. The display device as claimed in claim 31, wherein the drain electrode includes sections extending parallel to the pair of first data lines and the second data line.

33. A method of fabricating a thin film transistor substrate of a display device, the method comprising:
(a) forming a gate line on a base substrate;
(b) forming a data line including a first data line insulated from and intersected with the gate line and a second data line intersecting the first data line and having an end electrically connected to the first data line; and
(c) arranging a drain electrode to be spaced apart from the data line by a predetermined interval,
wherein a line width of the gate line is at least greater than a line width of the second data line.

34. The method as claimed in claim 33, further comprising forming the second data line in parallel to the gate line.

35. The method as claimed in claim 33, wherein arranging the drain electrode comprises forming the drain electrode parallel to the second data line.

36. The method as claimed in claim 33, further comprising forming the second data line such that a first portion thereof is parallel to the gate line and a second portion thereof is parallel to the first data line.

37. The method as claimed in claim 36, wherein arranging the drain electrode comprises forming the drain electrode parallel to the second data line.

38. The method as claimed in claim 33, wherein arranging the drain electrode comprises forming the drain electrode parallel to the first and second data lines.

39. A method of fabricating a thin film transistor substrate of a display device, the method comprising:
(a) forming a gate line on a base substrate;
(b) forming a pair of first data lines insulated from and intersected with the gate line and arranged in parallel to each other at a predetermined interval, and a second data line electrically connected to the pair of first data lines; and
(c) arranging a drain electrode to be spaced apart from the data line by a predetermined interval,
wherein a line width of the gate line is at least greater than a line width of the second data line.

40. The method as claimed in claim 39, wherein arranging the drain electrode comprises forming portions of the drain electrode parallel to the pair of first data lines and the second data line.

41. A method of fabricating a thin film transistor substrate of a display device, the method comprising:
determining a maximum misalignment range between a gate line and elements of a TFT within the thin film transistor substrate; and,
forming a line width of the gate line to be greater than the maximum misalignment range.

42. The method as claimed in claim 41, wherein determining a maximum misalignment range includes determining an expansion or shrinkage rate of a base substrate of the thin film transistor substrate.
